(19) United States
(12) Patent Application Publication
(10) Pub. No.: US 2025/0331342 A1
(43) Pub. Date: Oct. 23, 2025

(54) ENHANCED BOND PAD CONFIGURATION FOR A LIGHT EMITTING DIODE (LED) CHIP OF A SURFACE MOUNTABLE PACKAGE UTILIZING A GOLD BALL THAT HAS BEEN APPLIED TO A METAL LAYER OF THE LED CHIP

(71) Applicant: Dominant Opto Technologies Sdn Bhd., Melaka (MY)

(72) Inventors: LOW TEK BENG, MELAKA (MY); KAM PING ANG, MELAKA (MY); LIM CHEE SHENG, MELAKA (MY)

(21) Appl. No.: 18/803,297

(22) Filed: Aug. 13, 2024

(30) Foreign Application Priority Data
Apr. 23, 2024 (MY) PI 2024002343
Jun. 11, 2024 (MY) PI 2024003377

(51) Int. Cl. H01L 33/62; H01L 23/00; H01L 33/48

(52) U.S. Cl. CPC H10H 20/857; H01L 24/05; H01L 24/45; H01L 24/48; H10H 20/8506; H01L 2224/04042; H01L 2224/05144; H01L 2224/056; H01L 2224/45144; H01L 2224/48245; H01L 2224/48463

(57) ABSTRACT

An enhanced bond pad configuration for a light emitting diode (LED) chip of a surface mountable package is presented herein. The surface mountable package comprises an LED chip that has been bonded, within a cavity of the surface mountable package, to a lead frame. The LED chip comprises a first metal layer that has been formed on a first gold bond pad that has been formed on a substrate of the LED chip, or a second gold bond pad that has been formed on the substrate and that surrounds a second metal layer that has been formed on the substate. The surface mountable package further comprises a gold wire that has been ball bonded, via a gold ball, onto the first metal layer or the second metal layer to electrically couple the LED chip to the lead frame.

### CROSS-REFERENCE TO RELATED APPLICATIONS

The subject patent application claims priority under 35 U.S.C. § 119 to each of Malaysia Patent Application No. PI2024003377, filed on Jun. 11, 2024, and entitled “ENHANCED BOND PAD CONFIGURATION FOR A LIGHT EMITTING DIODE CHIP OF A SURFACE MOUNTABLE PACKAGE UTILIZING A GOLD BALL THAT HAS BEEN APPLIED TO A METAL LAYER OF THE LED CHIP,” which claims priority to Malaysia Patent Application No. PI2024002343, filed on Apr. 23, 2024, and entitled “ENHANCED BOND PAD CONFIGURATION FOR A LIGHT EMITTING DIODE CHIP OF A SURFACE MOUNTABLE PACKAGE UTILIZING A GOLD BALL THAT HAS BEEN APPLIED TO AN ALUMINUM OR ALUMINIUM LAYER OF THE LED CHIP”, the entirety of which applications are hereby incorporated by reference herein.

### TECHNICAL FIELD

The subject disclosure generally relates to embodiments for an enhanced bond pad configuration for a light emitting diode (LED) chip of a surface mountable package utilizing a gold (Au) ball that has been applied to a metal layer of the LED chip.

### BACKGROUND

Conventional LED technologies use high bonding temperatures, e.g., greater than 220° Celsius, to form appropriate intermetallic diffusion between Au bumps and respective Au bond pads. To reduce damage to a plastic material of an LED package, e.g., burning and/or darkening of the plastic material, lower bonding temperatures, e.g., between 150-200° Celsius, can be used to form Au-to-Au bonds; however, use of such lower bonding temperatures leads to weakened Au-to-Au intermetallic diffusion and poor electrical conductivity. Further, conventional use of Al pond pads on an LED package results in Al bond bad corrosion under high humidity and/or corrosive conditions. In this regard, conventional LED technologies have had some drawbacks, some of which may be noted with reference to the various embodiments described herein below.

### BRIEF DESCRIPTION OF THE DRAWINGS

Non-limiting embodiments of the subject disclosure are described with reference to the following figures, wherein like reference numerals refer to like parts throughout the various views unless otherwise specified:

FIG. 1 illustrates a block diagram of a side view of a surface mountable package comprising an enhanced bond pad configuration for an LED chip utilizing an Au ball that has been applied to a metal layer of the LED chip, in accordance with various example embodiments;

FIG. 2 illustrates a block diagram of a side view of a substrate of an LED chip in which a metal layer has been formed on an Au bond pad that has been formed on the substrate of the LED chip, in accordance with various example embodiments;

FIG. 3 illustrates a block diagram of an enlarged image of an enhanced bond pad configuration for an LED chip in which an Au ball has been applied to a metal layer that has been formed on an Au bond pad that has been formed on a substrate of the LED chip, in accordance with various example embodiments;

FIG. 4 illustrates a block diagram of a side view of a substrate of an LED chip in which a metal layer has been formed on the substrate of the LED chip, and in which an Au bond pad that has been formed on the substrate surrounds the metal layer, in accordance with various example embodiments;

FIG. 5 illustrates a block diagram of an enlarged image of an enhanced bond pad configuration for an LED chip in which a metal layer has been formed on a substrate of the LED chip, and in which an Au bond that has been formed on the substrate surrounds the metal layer, in accordance with various example embodiments;

FIG. 6 illustrates a top view of an LED chip in which a metal layer has been formed on a substrate of the LED chip, and in which an Au bond pad that has been formed on the substrate surrounds the metal layer, in accordance with various example embodiments; and

FIG. 7 illustrates respective instances of good and poor Au-to-Au intermetallic diffusion, in accordance with various example embodiments.

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

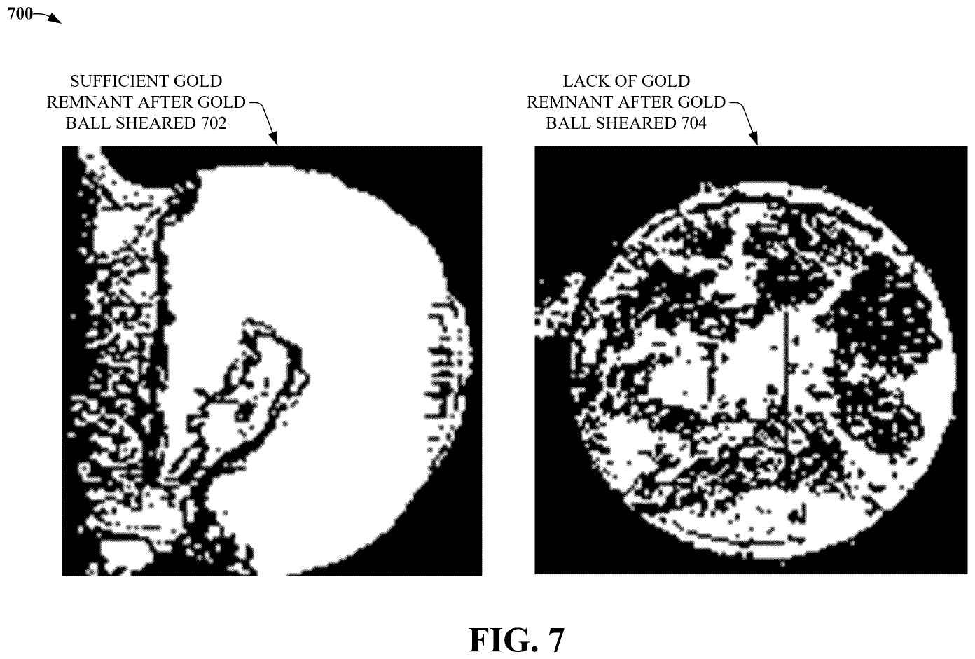

Referring now to FIG. 7, high wire bonding temperatures, e.g., greater than 220° Celsius, are used to form appropriate intermetallic diffusion between Au bumps and respective Au bond pads; and sufficient Au remnant (702) is present after an Au ball, which has been bonded to an Au bond pad using the high bonding temperatures, has been sheered. However, damage to a plastic material of an LED package (e.g., darkening, browning, and/or burning of the plastic) results from using the high wire bonding temperatures for bonding Au balls to Au bond pads of an LED chip of the LED package. Such damage compromises a light output (e.g., light output intensity, light output brightness, and/or light output color) of the LED chip.

Although using lower bonding temperatures, e.g., between 150-200° Celsius, to bond an Au ball to an Au bond pad can prevent damage to the plastic material of the LED package from occurring, using the lower bonding temperatures results in reduced, weakened, and/or poor Au-to-Au intermetallic diffusion and lower electrical conductivity of the Au bond pad; and lack of Au remnant (704) is present after an Au ball, which has been bonded to an Au bond pad using the lower bonding temperatures, has been sheered.

Further, using Al bonds pads on an LED package results in Al bond bad corrosion under high humidity and/or corrosive conditions.

On the other hand, various embodiments disclosed herein provide for an enhanced bond pad configuration for an LED chip of a surface mountable package by utilizing an Au ball that has been applied to a metal layer that has been formed on an Au bond pad that has been formed on a substrate of the LED chip, or by utilizing an Au ball that has been applied to a metal layer, e.g., comprising aluminum (Al), aluminium, palladium (Pd), copper (Cu), and/or another metal that has been formed on the substrate—in which an Au bond pad that has been formed on the substrate surrounds the metal layer.

For example, in an embodiment, an optoelectronic component comprises a surface mountable package, the surface mountable package comprising: an LED chip that has been bonded, within a cavity of the surface mountable package, to a lead frame of the surface mountable package, in which the LED chip comprises a metal layer (e.g., comprising Al, aluminium, Pd, Cu, and/or another metal) that has been formed on an Au bond pad that has been formed on a substrate of the LED chip; and an Au wire that has been ball bonded, via an Au ball, onto the metal layer to electrically couple the LED chip to the lead frame.

In one embodiment, a surface area of the metal layer is equal, within a defined percentage tolerance (e.g., within 10%), to one-third of a pad surface area of the Au bond pad.

In another embodiment, a first thickness of the metal layer is equal, within a defined percentage tolerance (e.g., within 10%), to a second thickness of the Au bond pad.

In yet another embodiment, a diameter of the Au ball is equal, within a defined percentage tolerance (e.g., within 10%), to a bond pad diameter of the Au bond pad.

In an embodiment, the surface mountable package further comprises a plastic housing that surrounds the cavity.

In one embodiment, the surface mountable package further comprises an encapsulant material, e.g., a translucent or transparent encapsulant material, that covers the LED chip. In another embodiment, the encapsulant material has been added, injected, transfer-molded, and/or filled into the cavity.

In yet another embodiment, a light emitting surface of the encapsulant material facilitates a transmission, via the LED chip, of electromagnetic radiation comprising visible light, infrared light, and/or ultraviolet light.

In an embodiment, an optoelectronic component comprises a surface mountable package, the surface mountable package comprising: an LED chip that has been bonded, within a cavity of the surface mountable package, to a lead frame of the surface mountable package, in which the LED chip comprises an Au bond pad that has been formed on a substrate of the LED chip and that surrounds a metal layer (e.g., comprising Al, aluminium, Pd, Cu, and/or another metal) that has been formed on the substate; and an Au wire that has been ball bonded, via an Au ball, onto the metal layer to electrically couple the LED chip to the lead frame.

In one embodiment, a surface area of the metal layer is equal, within a defined percentage tolerance (e.g., within 10%), to one-third of a pad surface area of the Au bond pad.

In another embodiment, a first thickness of the metal layer is greater than a second thickness of the Au bond pad.

In yet another embodiment, a diameter of the Au ball is equal, within a defined percentage tolerance (e.g., within 10%), to a bond pad diameter of the Au bond pad.

In an embodiment, the surface mountable package further comprises a plastic housing that surrounds the cavity.

In one embodiment, the surface mountable package further comprises an encapsulant material covering the LED chip, e.g., the encapsulant material being translucent or transparent. In another embodiment, the encapsulant material has been added, injected, transfer-molded, and/or filled into the cavity.

In yet another embodiment, a light emitting surface of the encapsulant material facilitates a transmission, via the LED chip, of electromagnetic radiation comprising visible light, infrared light, and/or ultraviolet light.

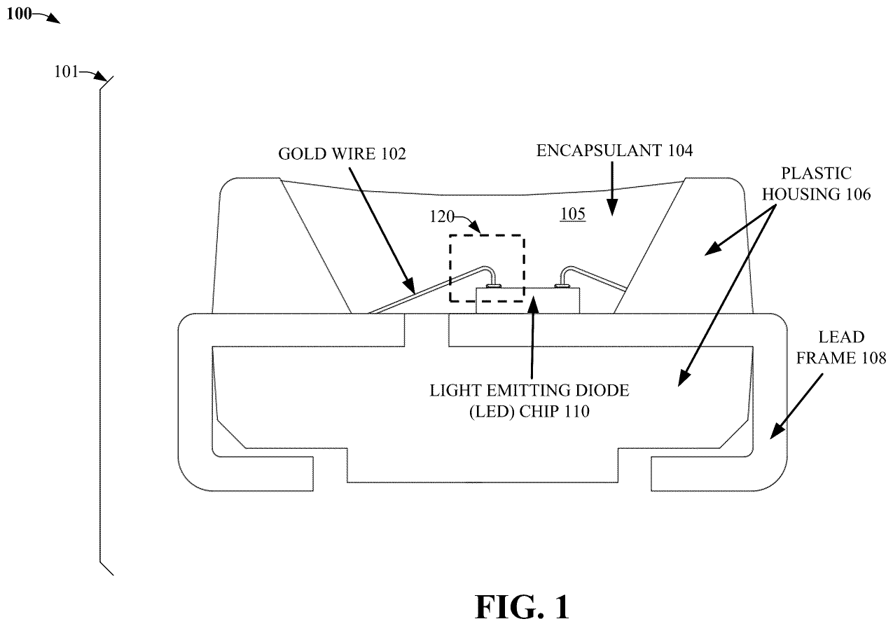

Referring now to FIGS. 1-3, block diagrams of a side view of an optoelectronic component (100) that comprises a surface mountable package (101) comprising an enhanced bond pad configuration (120) for an LED chip (110) utilizing an Au ball (302) that has been applied to a metal layer (202) of the LED chip; a side view (200) of a substrate (201) of the LED chip in which a metal layer (202) has been formed on an Au bond pad (204) that has been formed on the substrate of the LED chip; and an enlarged image (300) of the enhanced bond pad configuration for the LED chip in which an Au ball (302) has been applied to the metal layer (202) that has been formed on the Au bond pad (204) that has been formed on the substrate of the LED chip are illustrated, respectively, in accordance with various example embodiments.

As illustrated by FIG. 1, the surface mountable package comprises a plastic housing (106) that surrounds a cavity (105) of the surface mountable package, and an LED chip (110) that has been bonded, within the cavity, to a lead frame (108) of the surface mountable package.

The surface mountable package further comprises an encapsulant material (e.g., encapsulant 104) that covers the LED chip. In an embodiment, the encapsulant material is translucent or transparent. In another embodiment, the encapsulant material has been added, injected, transfer-molded, and/or filled into the cavity.

In yet another embodiment, a light emitting surface of the encapsulant material facilitates a transmission, via the LED chip, of electromagnetic radiation comprising visible light, infrared light, and/or ultraviolet light.

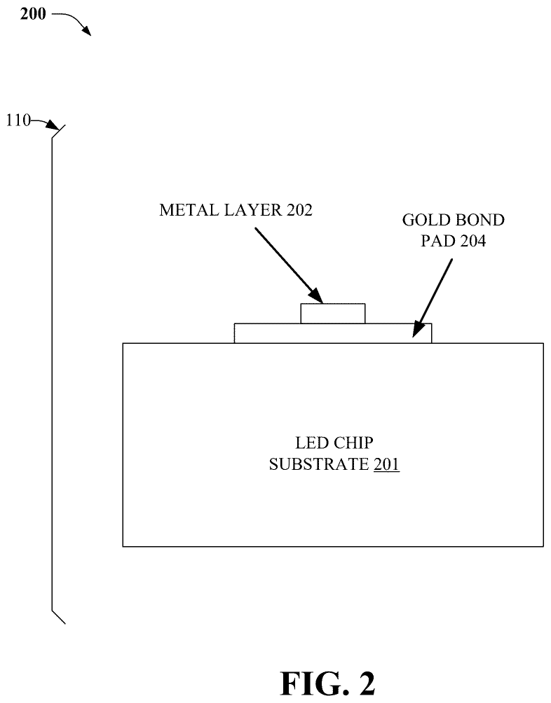

In an embodiment illustrated by FIG. 2, the LED chip comprises a metal layer (202) (e.g., comprising Al, aluminium, Pd, Cu, and/or another metal) that has been formed on an Au bond pad (204) that has been formed on a substrate (201) of the LED chip.

In one embodiment, a surface area of the metal layer is equal, within a defined percentage tolerance (e.g., within 10%), to one-third of a pad surface area of the Au bond pad.

In another embodiment, a first thickness of the metal layer is equal, within a defined percentage tolerance (e.g., within 10%), to a second thickness of the Au bond pad.

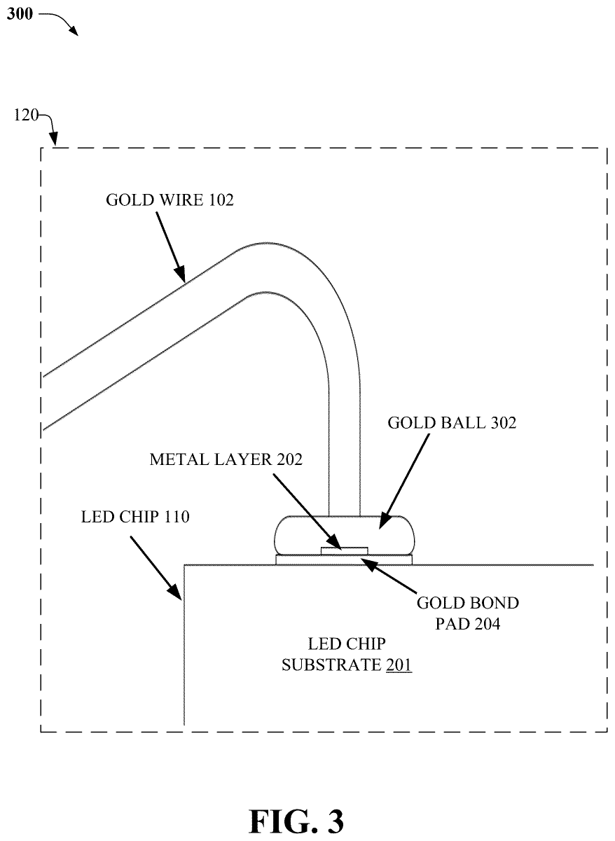

Referring now to an embodiment illustrated by FIG. 3, an Au wire (102) has been ball bonded, via an Au ball (302), onto the metal layer (202) (e.g., comprising Al, aluminium, Pd, Cu, and/or another metal) to electrically couple the LED chip to the lead frame of the surface mountable package.

In one embodiment, a diameter of the Au ball is equal, within a defined percentage tolerance (e.g., within 10%), to a bond pad diameter of the Au bond pad.

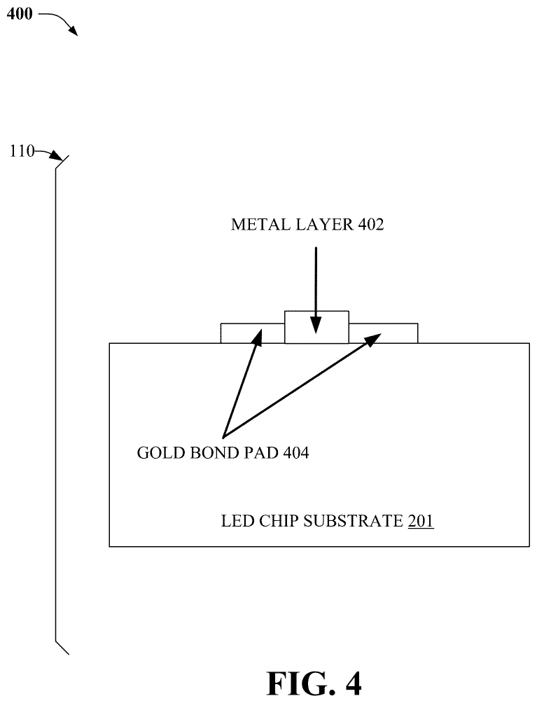

Referring now to an embodiment illustrated by FIG. 4, the LED chip comprises a metal layer (402) (e.g., comprising Al, aluminium, Pd, Cu, and/or another metal) that has been formed on the substrate (201) of the LED chip; and an Au bond pad (404) that has been formed on the substrate and that surrounds the metal layer.

In one embodiment, a surface area of the metal layer is equal, within a defined percentage tolerance (e.g., within 10%), to one-third of a pad surface area of the Au bond pad.

In another embodiment, a first thickness of the metal layer is greater than a second thickness of the Au bond pad.

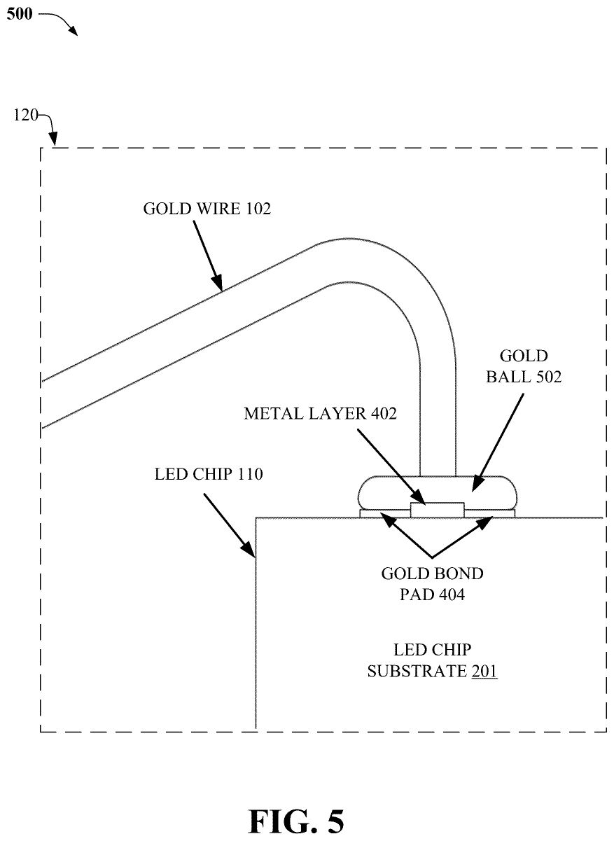

Referring now to an embodiment illustrated by FIG. 5, an Au wire (102) has been ball bonded, via an Au ball (502), onto the metal layer (402) to electrically couple the LED chip to the lead frame of the surface mountable package.

In one embodiment, a diameter of the Au ball is equal, within a defined percentage tolerance (e.g., within 10%), to a bond pad diameter of the Au bond pad.

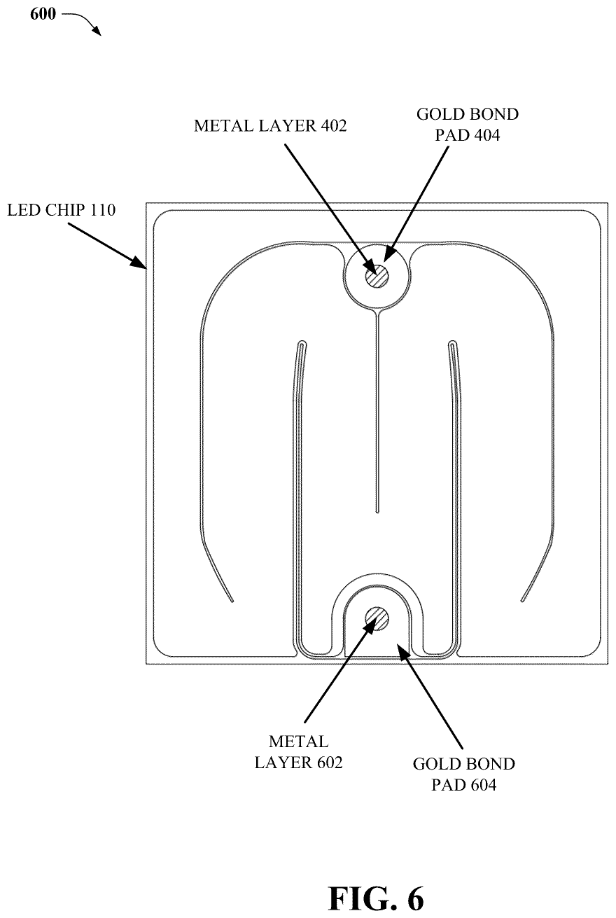

FIG. 6 illustrates a top view (600) of an LED chip (110), in which a metal layer (402, 602) (e.g., comprising Al, aluminium, Pd, Cu, and/or another metal) has been formed on a substrate (201) of the LED chip, and in which an Au bond pad (404, 604) has been formed on the substrate and surrounds the metal layer, in accordance with various example embodiments.

Reference throughout this specification to “one embodiment,” “an embodiment,” “another embodiment”, or “yet another embodiment” means that a particular feature, structure, or characteristic described in connection with the embodiment is included in at least one embodiment. Thus, the appearances of the phrase “in one embodiment,” “in an embodiment,” “in another embodiment”, and “in yet another embodiment” in various places throughout this specification are not necessarily all referring to the same embodiment. Furthermore, the particular features, structures, or characteristics may be combined in any suitable manner in one or more embodiments.

Further, to the extent that the terms “includes,” “has,” “contains,” and other similar words are used in either the detailed description or the appended claims, such terms are intended to be inclusive—in a manner similar to the term “comprising” as an open transition word-without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art having the benefit of the instant disclosure.

The above description of illustrated embodiments of the subject disclosure is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. An optoelectronic component comprising a surface mountable package, the surface mountable package comprising:
a light emitting diode (LED) chip that has been bonded, within a cavity of the surface mountable package, to a lead frame of the surface mountable package, wherein the LED chip comprises a metal layer that has been formed on a gold bond pad that has been formed on a substrate of the LED chip; and
a gold wire that has been ball bonded, via a gold ball, onto the metal layer to electrically couple the LED chip to the lead frame.

2. The optoelectronic component of claim 1, wherein the metal layer comprises at least one of aluminum, aluminium, palladium, copper, or another metal.

3. The optoelectronic component of claim 1, wherein a surface area of the metal layer is equal, within a defined percentage tolerance, to one-third of a pad surface area of the gold bond pad.

4. The optoelectronic component of claim 1, wherein a first thickness of the metal layer is equal, within a defined percentage tolerance, to a second thickness of the gold bond pad.

5. The optoelectronic component of claim 1, wherein a diameter of the gold ball is equal, within a defined percentage tolerance, to a bond pad diameter of the gold bond pad.

6. The optoelectronic component of claim 1, wherein the surface mountable package further comprises a plastic housing that surrounds the cavity.

7. The optoelectronic component of claim 1, wherein the surface mountable package further comprises an encapsulant material covering the LED chip.

8. The optoelectronic component of claim 7, wherein the encapsulant material has been at least one of added, injected, transfer-molded, or filled into the cavity.

9. The optoelectronic component of claim 7, wherein the encapsulant material is translucent or transparent.

10. The optoelectronic component of claim 7, wherein a light emitting surface of the encapsulant material facilitates a transmission, via the LED chip, of electromagnetic radiation comprising at least one of visible light, infrared light, or ultraviolet light.

11. An optoelectronic component comprising a surface mountable package, the surface mountable package comprising:
a light emitting diode (LED) chip that has been bonded, within a cavity of the surface mountable package, to a lead frame of the surface mountable package, wherein the LED chip comprises a gold bond pad that has been formed on a substrate of the LED chip and that surrounds a metal layer that has been formed on the substate; and
a gold wire that has been ball bonded, via a gold ball, onto the metal layer to electrically couple the LED chip to the lead frame.

12. The optoelectronic component of claim 11, wherein the metal layer comprises at least one of aluminum, aluminium, palladium, copper, or another metal.

13. The optoelectronic component of claim 11, wherein a surface area of the metal layer is equal, within a defined percentage tolerance, to one-third of a pad surface area of the gold bond pad.

14. The optoelectronic component of claim 11, wherein a first thickness of the metal layer is greater than a second thickness of the gold bond pad.

15. The optoelectronic component of claim 11, wherein a diameter of the gold ball is equal, within a defined percentage tolerance, to a bond pad diameter of the gold bond pad.

16. The optoelectronic component of claim 11, wherein the surface mountable package further comprises a plastic housing that surrounds the cavity.

17. The optoelectronic component of claim 11, wherein the surface mountable package further comprises an encapsulant material covering the LED chip.

18. The optoelectronic component of claim 17, wherein the encapsulant material has been at least one of added, injected, transfer-molded, or filled into the cavity.

19. The optoelectronic component of claim 17, wherein the encapsulant material is translucent or transparent.

20. The optoelectronic component of claim 17, wherein a light emitting surface of the encapsulant material facilitates a transmission, via the LED chip, of electromagnetic radiation comprising at least one of visible light, infrared light, or ultraviolet light.
